(19) United States
(12) Patent Application Publication
(10) Pub. No.: US 2017/0062303 A1
(43) Pub. Date: Mar. 2, 2017

(54) CIRCUIT CHIP MODULE HEAT DISSIPATION STRUCTURE

(71) Applicant: ADLINK TECHNOLOGY INC., New Taipei City (TW)

(72) Inventor: Chie-Ta LEE, New Taipei City (TW)

(21) Appl. No.: 14/840,946

(22) Filed: Aug. 31, 2015

(51) Int. Cl. H01L 23/367; H01L 23/373; H01L 31/024; H01L 23/498; H01L 27/146

(52) U.S. Cl. CPC H01L 23/3675; H01L 23/49838; H01L 27/14618; H01L 31/024; H01L 23/3736

(57) ABSTRACT

A circuit chip module heat dissipation structure includes a circuit module including a circuit board and a chip unit mounted at the circuit board, and a heat dissipation device consisting of a plurality of heat-transfer blocks bonded to the surface of the circuit board and abutted against the peripheral walls of the chip unit to create a heat-transfer path for transferring heat from the chip unit for quick dissipation.

### BACKGROUND OF THE INVENTION

1. Field of the Invention

The present invention relates to heat dissipation technology and more particularly, to a circuit chip module heat dissipation structure, which has heat-transfer blocks of a heat dissipation device bonded to a top surface of a circuit board and abutted against respective peripheral sides of a chip unit at the circuit board for absorbing heat from the chip unit directly for quick dissipation.

2. Description of the Related Art

Following fast development of technology, advanced computers and in response to computer equipment software and hardware standardization under the open architecture, computer functions have been continuously expanded and upgraded. Nowadays, various advanced industrial computers have been created for industrial control, industrial automation, measurement, network and communications equipment, machine vision and motion control applications. These advanced industrial computers can also be used in medical industry, national defense, transportation industry and aerospace industry that require high reliability and stability for the implementation of high performance under harsh environments and specific specifications.

Machine vision has been widely used in different industries for production fabrication and quality inspection for years. The application of machine vision can improve inspection accuracy and accelerate productivity. Therefore, image capture device has become a requisite apparatus in many production line inspection equipment. With machine vision technology innovation, various advanced machine vision devices have been created for digital security surveillance, video and 3D vision guided robot applications to meet different requirements for high-resolution, high frame rate and transmission, processing and interpretation of large image data. The application of advanced machine vision devices can also help increase production output and reduce production cost.

A regular machine vision inspection system generally comprises a light source, a camera, an image processor, a display screen, and etc. Regular cameras for industrial application can be divided into a line-scan type and an area-scan type. During operation, the image sensor of the camera transmits the image signal that is captured through the lens to the image processor for further analysis and storage or for display on a display screen directly. Due to high operating speed, the image sensor, field-programmable gate array (FPGA), central processing unit (CPU), chipset and/or other components at the internal circuit board of the camera release a large amount of waste heat during their operation. Therefore, maintaining the operation of these components within a specified temperature range is the key point to ensure a high level of system reliability. Thus, how to improve system heat dissipation efficiency is an important task in the creation of a machine vision inspection system.

### SUMMARY OF THE INVENTION

The present invention has been accomplished under the circumstances in view. It is therefore one object of the present invention to provide a circuit chip module heat dissipation structure, which comprises a circuit module comprising a circuit board and a chip unit mounted at the circuit board, and a heat dissipation device consisting of a plurality of heat-transfer blocks bonded to the surface of the circuit board and abutted against the peripheral walls of the chip unit to create a heat-transfer path for transferring heat from the chip unit for quick dissipation. Thus, during operation of the chip unit of the circuit module, waste heat released by the chip unit is directly and uniformly transferred to the heat-transfer blocks of the heat dissipation device for quick dissipation, enhancing chip unit heat dissipation efficiency.

Other advantages and features of the present invention will be fully understood by reference to the following specification in conjunction with the accompanying drawings, in which like reference signs denote like components of structure.

### BRIEF DESCRIPTION OF THE DRAWINGS

FIG. 1 is an oblique top elevational view of a circuit chip module heat dissipation structure in accordance with the present invention.

FIG. 2 is an exploded view of the circuit chip module heat dissipation structure in accordance with the present invention.

FIG. 3 is a sectional side view of the circuit chip module heat dissipation structure in accordance with the present invention.

FIG. 4 is an exploded view illustrating the circuit chip module heat dissipation structure of the present invention used in an image capture device.

FIG. 5 corresponds to FIG. 4 when viewed from another angle.

FIG. 6 is a sectional assembly view of FIG. 4.

### DETAILED DESCRIPTION OF THE PREFERRED EMBODIMENT

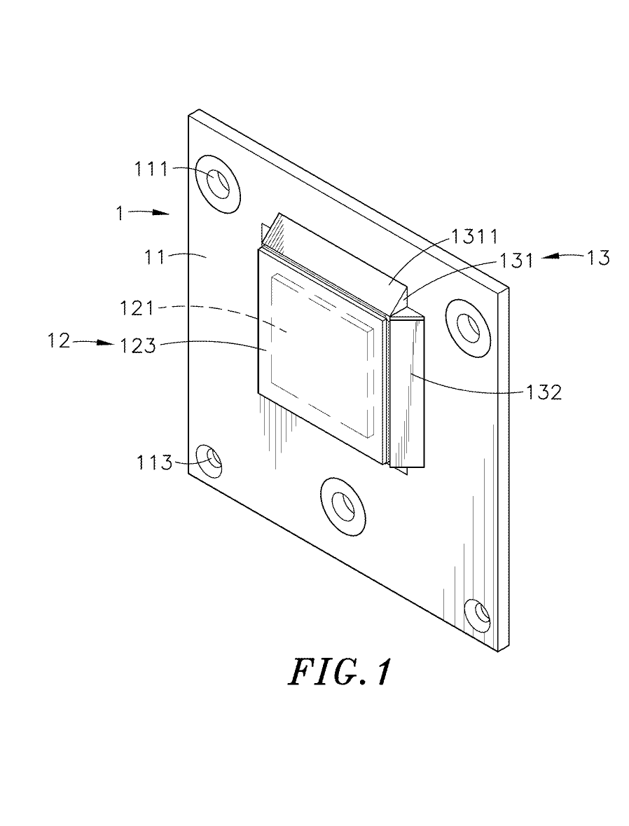

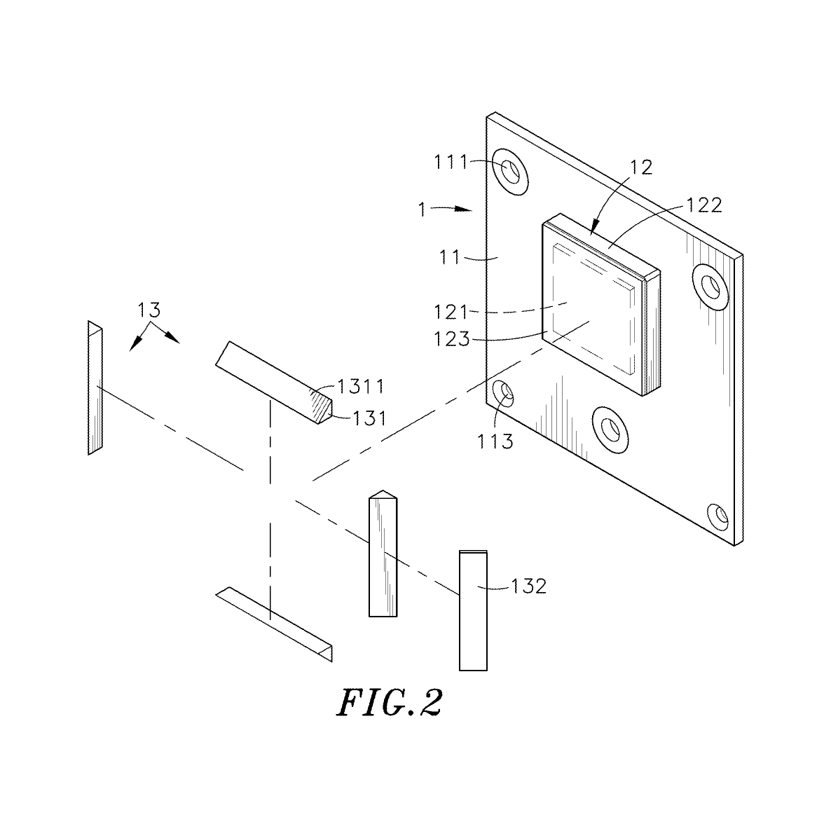

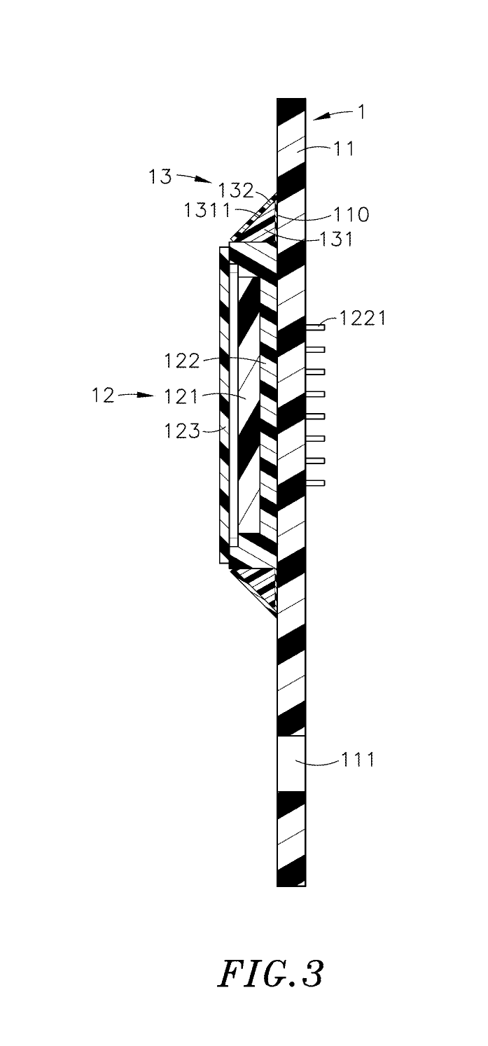

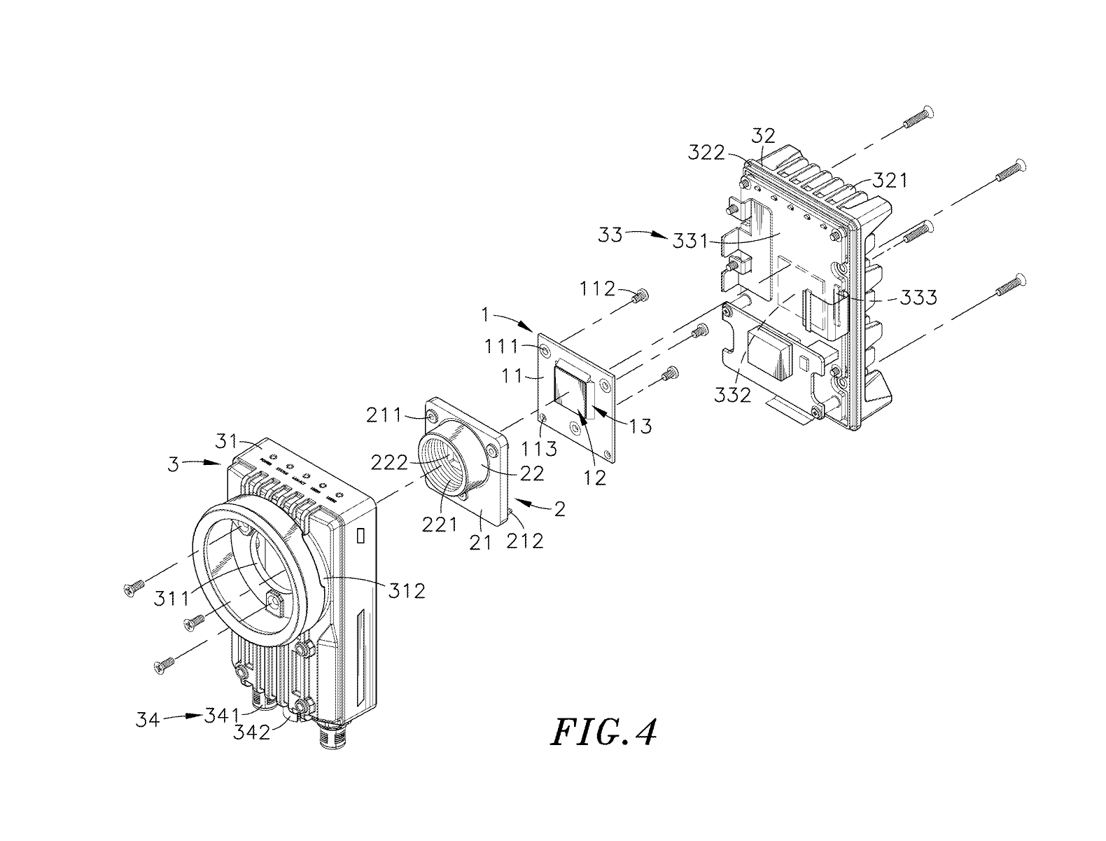

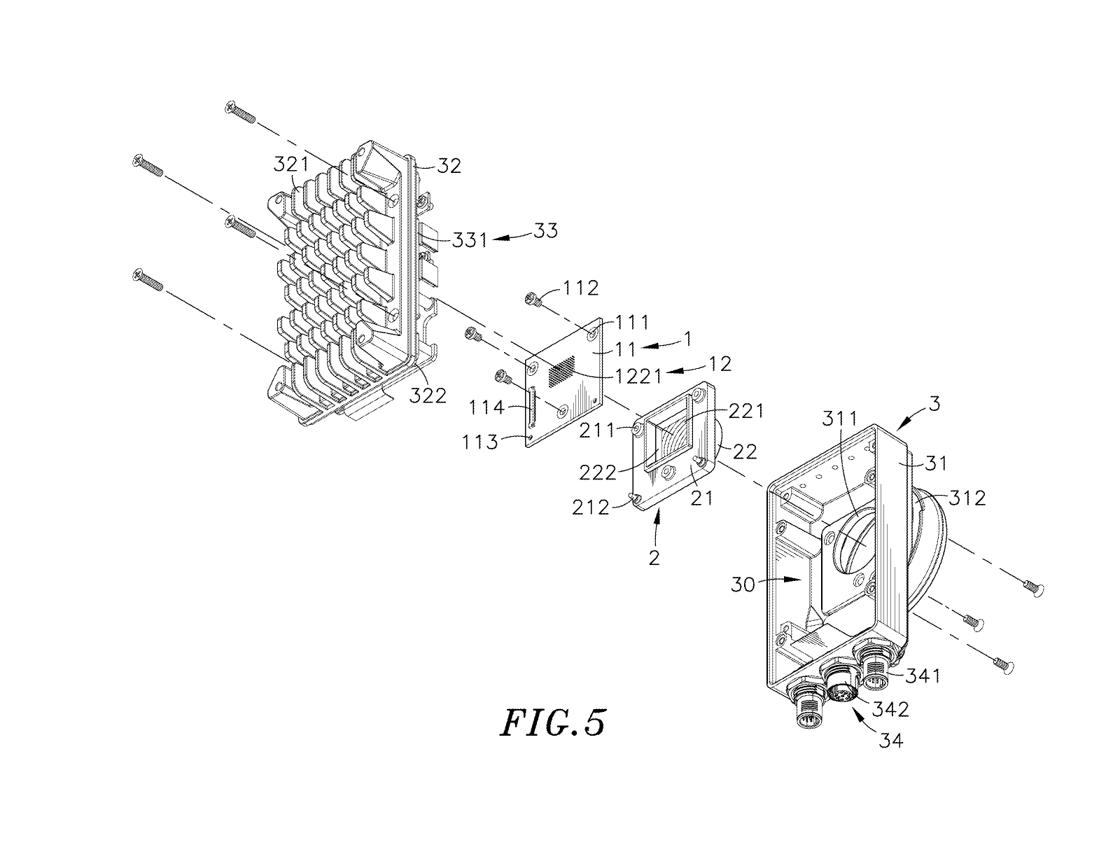

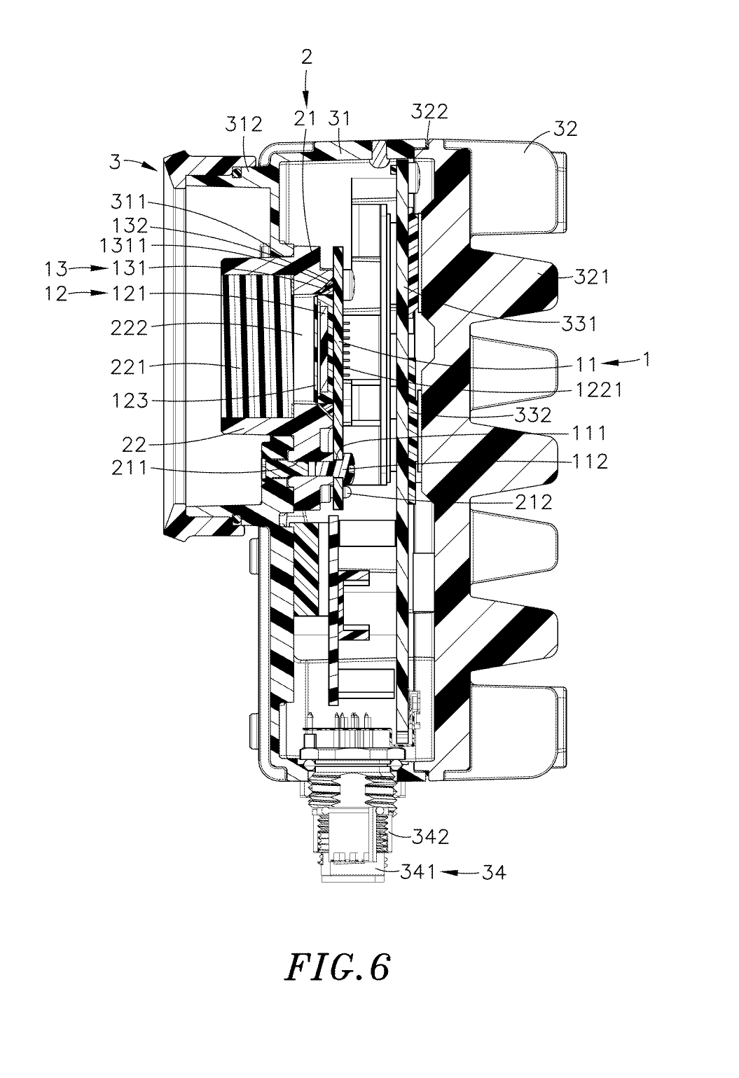

Referring to FIGS. 1-3, an oblique top elevational view of a circuit chip module heat dissipation structure, an exploded view of the circuit chip module heat dissipation structure and a sectional side view of the circuit chip module heat dissipation structure are shown. As illustrated, the circuit chip module heat dissipation structure comprises a circuit module 1. The circuit module 1 comprises a circuit board 11, at least one chip unit 12 mounted on a top surface of the circuit board 11. The chip unit 12 can be a complementary metal-oxide-semiconductor (CMOS) or charge-coupled device (CCD) chip. The circuit board 11 comprises a copper foil layer 110 located on the top surface thereof around the chip unit 12, a heat dissipation device 13 soldered to the copper foil layer 110, and a plurality of through holes 111 and mounting holes 113 cut through opposing top and bottom sides thereof and spaced around the chip unit 12 for the insertion of respective screws 112 (see also FIGS. 4-6). The heat dissipation device 13 comprises at least one, for example, multiple heat-transfer blocks 131. In this embodiment, the heat-transfer blocks 131 are right-angled triangular heat-transfer prisms. Each heat-transfer block (right-angled triangular heat-transfer prism) 131 has the two right-angled lateral faces thereof respectively bonded to the copper foil layer 110 at the top surface of the circuit board 11 and abutted against one respective peripheral side of the chip unit 12 to create a heat-transfer path with the height of the sloping lateral face (the third lateral face) 1311 thereof defined not larger than the height of the chip unit 12. Further, each heat-transfer block 131 is provided with a heat transfer medium 132. The heat transfer medium 132 can be a thermally conductive sheet or thermally paste bonded to the sloping lateral face 1311 of the heat-transfer block 131.

The circuit board 11 of the circuit module 1 has a circular layout arranged on the top surface thereof for the connection of the chip unit 12. In this embodiment, the heat dissipation device 13 comprises four heat-transfer blocks (right-angled triangular heat-transfer prisms) 131 soldered to the copper foil layer 110 of the circuit board 11 and respectively abutted to the four peripheral sides of the chip unit 12. However, this mounting arrangement is not a limitation. As an alternate form of the present invention, the heat-transfer blocks (right-angled triangular heat-transfer prisms) 131 can be bonded to the copper foil layer 110 of the circuit board 11 with a light-curable adhesive or chemical adhesive. In another alternate form of the present invention, the copper foil layer 110 can be eliminated, and the heat-transfer blocks (right-angled triangular heat-transfer prisms) 131 can be directly bonded to the top surface of the circuit board 11. As stated above, the heat dissipation device 13 is configured to provide multiple heat-transfer blocks 131 that are right-angled triangular heat-transfer prisms. However, this design is not a limitation. In actual application, the heat dissipation device 13 can be formed of multiple elongated or L-shaped heat-transfer blocks, or multiple heat-transfer blocks of any of a variety of other shapes for abutment against the peripheral sides of the chip unit 12 to create a heat-transfer path.

Further, the aforesaid chip unit 12 can be a complementary metal-oxide-semiconductor (CMOS), charge-coupled device (CCD) chip, field-programmable gate array (FPGA), central processing unit (CPU), graphics processing unit (GPU), graphics and memory controller hub (GMCH), network chip or other processing chip. In the case that the chip unit 12 is a charge-coupled device (CCD) chip, it comprises a chip 121, a chip carrier 122 carrying the chip 121, a plurality of pins 1221 inserted through the chip carrier 122 and electrically connected to the chip 121, and a lens layer 123 covered on the chip carrier 122 over the chip 121. In installation, the heat-transfer blocks 131 of heat dissipation device 13 are bonded to the copper foil layer 110 at the top surface of the circuit board 11 and abutted against the respective peripheral sides of the chip carrier 122 of the chip unit 12 to create a heat-transfer path. In actual application, the type and number of the chip unit 12 can be variously embodied to meet different application requirements.

As stated above, the heat-transfer blocks (right-angled triangular heat-transfer prisms) 131 of the heat dissipation device 13 are respectively abutted against the peripheral sides of the chip unit 12 of the circuit module 1 to create a heat-transfer path. During operation of the chip unit 12, waste heat can be rapidly transferred from the chip unit 12 through the heat-transfer blocks (right-angled triangular heat-transfer prisms) 131 of the heat dissipation device 13 for quick dissipation. Further, the heat-transfer blocks (right-angled triangular heat-transfer prisms) 131 of the heat dissipation device 13 can be prepared from copper, aluminum, ferrite to provide a large heat dissipation area so that the heat-transfer blocks (right-angled triangular heat-transfer prisms) 131 of the heat dissipation device 13 can efficient absorb heat from the chip unit 12 for quick dissipation. Further, the amount of heat that can be guided out of the chip unit 12 by the heat-transfer blocks (right-angled triangular heat-transfer prisms) 131 of the heat dissipation device 13 depends on the kind of material used for the heat-transfer blocks (right-angled triangular heat-transfer prisms) 131 of the heat dissipation device 13.

Referring to FIGS. 4-6, the circuit chip module heat dissipation structure of the invention can be used in an image capture device (for example, video camera), computer, notebook computer, server, embedded system or other computer-based apparatus. For use in an image capture device, the circuit module 1 is mounted with a lens holder 2 inside a housing 3. When mounting the circuit module 1 with the lens holder 2 in the housing 3, aim a lens aperture 222 in a mating connection portion 22 of the lens holder 2 at the chip unit 12 of the circuit module 1, and then move a base 21 of the lens holder 2 toward the circuit module 1 into abutment against the top surface of the circuit board 11 and simultaneously to force respective positioning rods 212 at a bottom side of the base 21 into respective mounting holes 113 of the circuit board 11, enabling the chip unit 12 to be inserted into the lens aperture 222. At this time, the heat-transfer blocks (right-angled triangular heat-transfer prisms) 131 of the heat dissipation device 13 are abutted against an inside wall of the lens holder 2 around the lens aperture 222, and respective screw holes 211 of the base 21 are respectively kept in axial alignment with the respective through holes 111 of the circuit board 11. Thereafter, insert respective screws 112 through the respective through hole 111 and thread them into the respective screw holes 211 of the base 21 to fixedly fasten the lens holder 2 and the circuit board 11 of the circuit module 1 together.

Thereafter, insert the mating connection portion 22 of the lens holder 2 through an opening 311 of a front cover shell 31 of the housing 3 to the outside of a front flange 312 of the front cover shell 31, enabling the lens holder 2 and the front cover shell 31 to be fixedly fastened together with screws 112. The housing 3 further comprises a back cover shell 32 carrying a control system 33 and covered on a back side of the front cover shell 31. The control system 33 comprises a circuit board 331, a chipset 332 mounted in the circuit board 331 and bonded to a surface of the back cover shell 32 with a heat transfer medium (not shown) to create a heat-transfer path, and a second electrical connector 333 mounted in the circuit board 331 and electrically connected to a first electrical connector 114 at the circuit board 11 of the circuit module 1 by a connection interface, such as flexible flat cable (FFC) or flexible printed circuit board (FPC). Further, the back cover shell 32 has a plurality of radiation fins 321 arranged at a back side thereof to increase its heat dissipation surface area. Thereafter, cover the back cover shell 32 on the back side of the front cover shell 31, and then use screws 112 to fasten the back cover shell 32 and the front cover shell 31 tightly together with a gasket ring 322 peripherally sealed between the back cover shell 32 and the front cover shell 31 to provide excellent waterproof and dust-sealing effects.

The mating connection portion 22 of the lens holder 2 defines therein a lens mounting hole 221 for the mounting of a camera lens. The housing 3 further comprises transmission interface means 34 electrically connected with the control system 33. The transmission interface means 34 comprises a power connector 341 and a signal connector 342 electrically connected to an industrial computer, network control automation system or other electronic apparatus with cable means. Thus, during operation of the chip unit 12 of the circuit module 1, the chip unit 12 converts incident light into a corresponding image signal and transmits the image signal to the chipset 332 of the control system 33 for image capture and storage, and the latent heat produced during operation of the chip unit 12 is transferred through the heat-transfer blocks (right-angled triangular heat-transfer prisms) 131 and heat transfer medium 132 of the heat dissipation device 13 to the lens holder 2 and then the front cover shell 31, back cover shell 32 and radiation fins 321 of the housing 3 for quick dissipation into the outside open air.

As described above, the circuit module 1 is characterized by the arrangement of the heat-transfer blocks (right-angled triangular heat-transfer prisms) 131 and heat transfer medium 132 of the heat dissipation device 13 on the top surface of the circuit board 11 to have the heat-transfer blocks (right-angled triangular heat-transfer prisms) 131 respectively abutted against the respective peripheral sides of the chip unit 12 for absorbing heat from the chip unit 12 directly for quick dissipation. Thus, during operation of the chip unit 12, waste heat can be directly transferred from the chip unit 12 through the heat-transfer blocks (right-angled triangular heat-transfer prisms) 131 of the heat dissipation device 13 for quick dissipation, maintaining system reliability.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. An circuit chip module heat dissipation structure, comprising a circuit module, said circuit module comprising a circuit board, at least one chip unit mounted at said circuit board, and a heat dissipation device mounted at said circuit board around each said chip unit, said heat dissipation device comprising at least one heat-transfer block abutted against multiple peripheral walls of each said chip unit to create a heat-transfer path for transferring heat from each said chip unit for dissipation.

2. The circuit chip module heat dissipation structure as claimed in claim 1, wherein said circuit board comprises a copper foil layer arranged on a top surface thereof around each said chip unit; said at least one heat-transfer block of said heat dissipation device is bonded to said copper foil layer and abutted against the peripheral sides of each said heat-transfer block of said heat dissipation device.

3. The circuit chip module heat dissipation structure as claimed in claim 1, wherein each said chip unit of said circuit module is selected from the group of complementary metal-oxide-semiconductor (CMOS) chips and charge-coupled device (CCD) chips.

4. The circuit chip module heat dissipation structure as claimed in claim 1, wherein each said heat-transfer block of said heat dissipation device is a right-angled triangular heat-transfer prism having two right-angled lateral faces and a sloping lateral face, one of said two right-angled lateral faces being bonded to said copper foil layer of said circuit board, the other of said two right-angled lateral faces being abutted against one respective said peripheral side of one respective said chip unit, the height of said sloping lateral face being smaller than the height of the peripheral sides of said at least one chip unit.

5. The circuit chip module heat dissipation structure as claimed in claim 4, wherein said heat dissipation device further comprises a heat transfer medium located at each said heat-transfer block, said heat transfer medium being selected from the group of thermally conductive sheet and thermally paste and mounted at the sloping lateral face of each said heat-transfer block.

6. The circuit chip module heat dissipation structure as claimed in claim 1, wherein said at least one heat-transfer block of said heat dissipation device is selected from the group of copper, aluminum and ferrite.
